(19) United States
(12) Patent Application Publication
(10) Pub. No.: US 2020/0227612 A1
(43) Pub. Date: Jul. 16, 2020

(54) THERMOELECTRIC GENERATOR

(71) Applicant: CENTRE NATIONAL DE LA RECHERCHE SCIENTIFIQUE, Paris (FR)

(72) Inventors: Jean-Luc GARDEN, Echirolles (FR); Emmanuel ANDRE, Meylan (FR); Gaël MOIROUX, Grenoble (FR)

(21) Appl. No.: 16/639,053

(22) PCT Filed: Aug. 3, 2018
(86) PCT No.: PCT/EP2018/071185

§ 371 Date: Feb. 13, 2020

(30) Foreign Application Priority Data
Aug. 24, 2017 (FR) 1757846

(51) Int. Cl. H01L 35/32

(52) U.S. Cl. CPC H01L 35/32

(57) ABSTRACT

An electricity generator including a suspended membrane resting on a frame, the membrane bearing alternating thermoelectric tracks connected in series and each having one end on the frame and one end on a central part of the membrane, wherein the membrane is deformable, the central parts of the membrane being intended to be in mechanical and thermal contact with a heat source.

### TECHNICAL FIELD

The present application relates to a thermoelectric generator, converting thermal energy into electricity.

### DESCRIPTION OF THE PRIOR ART

For certain electricity production applications, a thermoelectric generator in contact with a heat source is used. The heat source is typically a pipe in which a hot fluid circulates, for example hotter than the ambient air, a heat pipe or a metallic heat transfer tube. The heat supplied by the source can have various origins. For example, this heat can come from a heat storage element replenished during the day by the sun and used at night in order to produce electricity. This heat can also originate, in an industrial installation, from heat loss which is recovered in order to produce electricity.

FIGS. 1A and 1B are respectively a diagrammatic cross section view and a diagrammatic top view of an example of a thermoelectric generator, in contact with a heat source.

A suspended membrane 102 rests on a frame 104. Thermoelectric tracks of two different types 110, 112 rest on the membrane 102 (the tracks 112 are only visible in FIG. 1B). Although 12 tracks are represented as an example, in practice there can be between 2 and more than 100 tracks present. The two types of tracks are, for example, chromel and constantan, copper and constantan, or can correspond to the N-type and P-type doping of a semiconductor, for example silicon or bismuth telluride, the two materials constituting the elements of a thermoelectric couple. The tracks are connected electrically in series, and thermally in parallel, the two types of tracks being alternate. When viewing the connection in series, the ends in contact between the consecutive tracks are situated alternately on the frame and on a central part of the membrane. The ends of the connection in series are equipped with electrical contact terminals 120 and 122.

A heat source 130, for example the end of a heat transfer tube, is in thermal and mechanical contact with the centre of the membrane.

In operation, the frame 104 is maintained at a temperature substantially equal to ambient temperature, for example by fastening the frame onto a radiator (not shown). The centre of the membrane 102 is heated by the source 130 and brought to a temperature greater than that of the frame. A voltage then appears between the terminals 120 and 122.

Various difficulties arise in bringing the central parts of the membrane into mechanical and thermal contact with the heat source. This results in various problems of implementation, efficiency, and/or deterioration of the membrane and/or of the tracks.

### SUMMARY

Thus, an embodiment makes provision for overcoming all or part of the drawbacks described above.

An embodiment makes provision for a thermoelectric generator that is particularly simple to put in mechanical and thermal contact with a heat source.

An embodiment makes provision for a thermoelectric generator with particularly increased efficiency.

An embodiment makes provision for a thermoelectric generator that is particularly robust.

An embodiment makes provision for a generator comprising a suspended membrane resting on a frame, the membrane bearing thermoelectric tracks of alternate types connected in series and each having one end on the frame and one end on a central part of the membrane, in which the membrane is deformable, the central parts of the membrane being intended to be in mechanical and thermal contact with a heat source.

According to an embodiment, the membrane is made from a polyimide.

According to an embodiment, the polyimide is thermostable.

According to an embodiment, the membrane has a thickness comprised between 10 and 100 μm.

According to an embodiment, the membrane comprises slits which extend between the tracks from a central point of the membrane.

According to an embodiment, the membrane comprises a central hole.

According to an embodiment, the tracks are wider towards the edges than towards the centre of the membrane, and, on the suspended parts of the membrane, the spaces between the adjacent tracks correspond to radial strips with a width less than 0.5 mm.

According to an embodiment, the central parts of the membrane are covered with a thermally conductive layer intended to form said mechanical and thermal contact.

According to an embodiment, the tracks are made from a doped semiconductor and the types of tracks are the N and P doping types.

An embodiment makes provision for a group of generators arranged in an array, comprising generators as above, electrically connected in series and/or in parallel.

### BRIEF DESCRIPTION OF THE FIGURES

These characteristics and advantages, as well as others, will be disclosed in detail in the following non-limitative description of particular embodiments with reference to the attached figures in which:

FIGS. 1A and 1B, described above, are respectively a diagrammatic cross section view and a diagrammatic top view of a thermoelectric generator;

FIG. 2 is a diagrammatic view in cross section of an embodiment of a thermoelectric generator in contact with a heat source;

FIG. 3A is a diagrammatic top view of another embodiment of a thermoelectric generator;

FIG. 3B is a diagrammatic view in cross section of the generator of FIG. 3A, in contact with a heat source;

FIG. 4A is a diagrammatic top view of another embodiment of a thermoelectric generator;

FIG. 4B is a diagrammatic view in cross section of the generator of FIG. 4A, in contact with a heat source; and

FIG. 5 is a diagrammatic top view of another embodiment of a thermoelectric generator.

### DETAILED DESCRIPTION

The same elements have been identified by the same references in the different figures and, moreover, the various figures are not drawn to scale. For the sake of clarity, only the elements useful to the understanding of the embodiments described have been represented and are detailed.

In the following description, when terms of relative position are referenced, such as the word “above”, reference is made to the orientation of the element concerned in the cross section views. Unless otherwise specified, the expression “substantially” means to within 10%, preferably to within 5%.

In the known devices of the type described in the preamble, the membrane 102 is typically based on silicon, for example silicon oxide or silicon nitride. These materials are currently used because they are well known in microfabrication processes, and in particular in lithography processes such as that used in order to produce the thermoelectric tracks. Here, it is proposed to use a deformable membrane, i.e. flexible and preferably extensible, i.e. the membrane is made from a material having an elongation at break greater than 20%, for example more than 40% or more than 70% at 25° C., and for example more than 60% at 300° C., or more than 80% at 200° C. The deformable membrane is for example a polyimide, preferably a thermostable polyimide such as an aromatic polyimide.

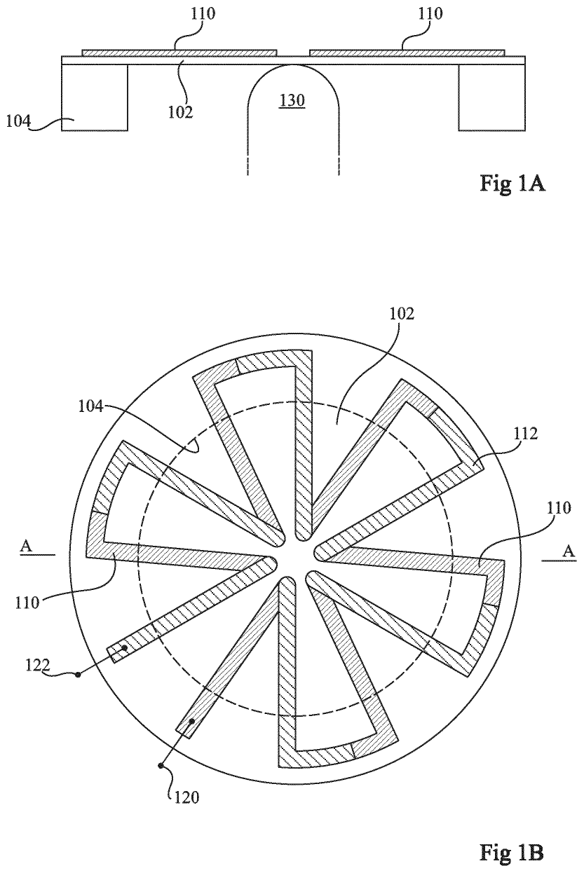

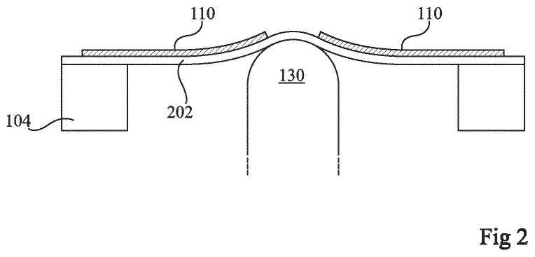

FIG. 2 is a diagrammatic view in cross section of an embodiment of a thermoelectric generator in contact with a heat source 130. The thermoelectric generator of FIG. 2 differs from the thermoelectric generator of FIG. 1 in that the membrane 102 is replaced by a deformable membrane 202. The other elements are identical or similar and arranged identically or similarly.

For example, the frame is circular with a diameter comprised between 1 and 2 cm. The thickness of the deformable membrane 202 is for example comprised between 10 and 100 μm.

According to an advantage, as the membrane 202 is deformable, it adopts locally, in the contact zone, the shape of the heat source 130. The thermal contact thus obtained between the source 130 and the membrane 202 is particularly good, and the generator therefore has a particularly high efficiency.

According to another advantage, the generator is particularly robust. In fact, the heat source may move with respect to the generator, in particular in the direction orthogonal to the membrane. This can occur for example after thermal expansions such as that of the heat source, for example causing elongation of the source when it is heated. As the membrane can deform, in the contact zone it follows the movement of the heat source, without this causing the membrane to break.

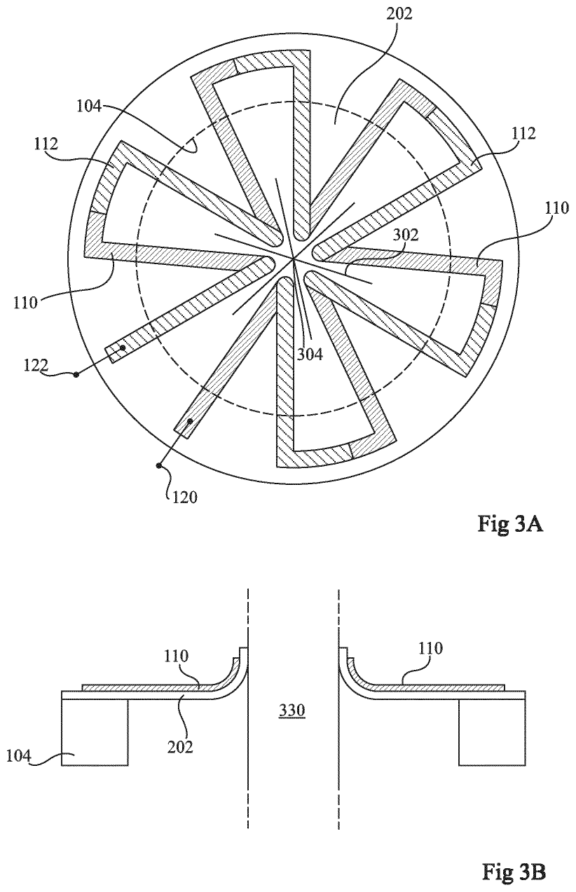

FIG. 3A is a diagrammatic top view of another embodiment of a thermoelectric generator. The thermoelectric generator of FIG. 3A differs from that of FIG. 2 in that the deformable membrane 202 comprises slits 302. The slits 302 pass through the thickness of the membrane and extend between the tracks from the centre of the membrane. For example, the frame is circular and the slits are regularly distributed. The slits are for example radial from a central point 304 of the membrane. For example, the slits 132 only affect the central parts of the membrane, i.e. they do not reach the frame 104.

FIG. 3B is a diagrammatic view in cross section of the thermoelectric generator of FIG. 3A in contact with a heat source. Here, the heat source 330 is a cylinder, for example a portion of a pipe, or a thermally conductive structure such as a metal rod or a heat pipe.

In order to produce the thermal contact, the device is held by the frame, and the centre of the membrane, preferably the opposite face to the tracks, is pressed onto the end (not shown) of the source 330. As the membrane 202 is flexible, the parts of the membrane situated between the slits 302 bend and the end of the source 330 passes through the membrane. The central parts of the membrane become pressed against the outer face of the source 330.

A thermal contact between the central parts of the membrane and a heat source of a cylindrical shape is thus obtained in a particularly simple way.

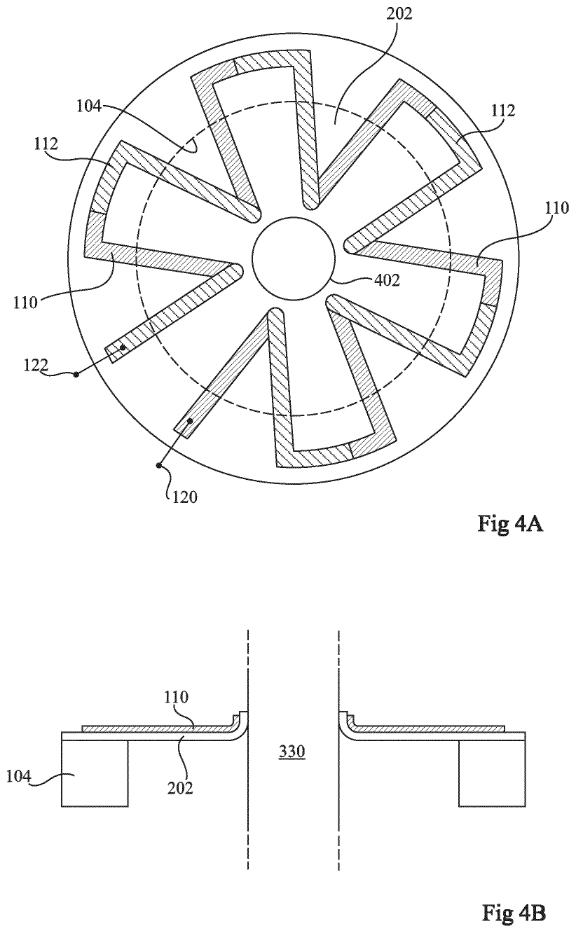

FIG. 4A is a diagrammatic top view of another embodiment of a thermoelectric generator. The generator of FIG. 4A differs from that of FIG. 2A in that the deformable membrane 202 has a central hole 402, for example a circular hole.

FIG. 4B is a diagrammatic view in cross section of the thermoelectric generator of FIG. 4A, in contact with a heat source 330, for example cylindrical.

Before installation, the hole 402 has a diameter slightly less, for example comprised between 2 and 20%, than that of the source 330. For installation, the procedure described above with respect to FIGS. 3A and 3B is carried out, which deforms the membrane around the hole and causes the end of the source to be passed through the membrane. Thus, a good thermal contact between the source 330 and the central parts of the membrane 202 is obtained in a particularly simple way.

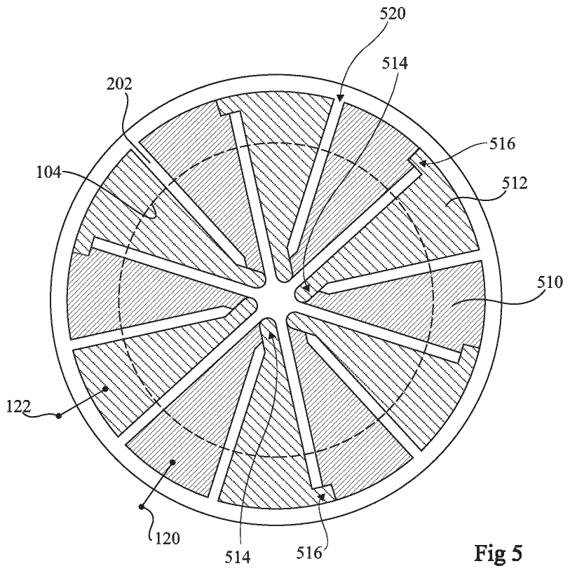

FIG. 5 is a diagrammatic top view of another embodiment of a thermoelectric generator. The thermoelectric generator of FIG. 5 differs from that of FIG. 2 in that the thermoelectric tracks 110 and 112 are replaced respectively by the thermoelectric tracks 510 and 512. Just like the thermoelectric tracks 110 and 112 of the generator of FIG. 2, the thermoelectric tracks 510 and 512 are electrically connected in series and thermally in parallel and are of two different alternate types. Just as for the tracks 110 and 112 of FIG. 2, when the serial association is viewed from the terminal 120 to the terminal 122, the contacts between ends of tracks are successively on a central part of the membrane (contact 514) and on the frame (contact 516).

The tracks 510 and 512 are wider near the frame 104 than towards the centre of the membrane 202. The spaces 520 between adjacent tracks have in a top view and beyond the end of the tracks, the shape of fine rectilinear strips, for example of strips with a thickness less than 0.5 mm, for example comprised between 10 μm and 0.5 mm, preferably less than 0.1 mm. Thus, the tracks 510 and 512 cover the largest surface possible of the suspended part of the membrane. This makes it possible to reduce the electrical resistance of the tracks for a given thickness, and therefore makes it possible to increase the conversion efficiency accordingly. Provision can thus be made for a reduced thickness of the tracks, for example less than 5 μm, for example comprised between 0.1 and 5 μm. As the tracks 510 and 512 are of reduced thickness, they are particularly flexible.

The thermoelectric tracks (110, 112; 510, 512) described in the different embodiments of the present invention originate from a deposition process known in the prior art. Such a process can be a thin layer process, such as vacuum evaporation or magnetron sputtering, or an electrodeposition process. A surface treatment, such as oxygen plasma treatment or the deposition of an adhesion promoter, can be applied to the membrane, in order to increase the adhesion of the tracks to the membrane.

Particular embodiments have been described. Various variants and modifications will become apparent to a person skilled in the art. In particular, in the embodiments described, provision can be made for a thermally conductive layer, for example made from copper, aluminium or gold, covering the central parts of the membrane. This conductive layer is preferably placed on the opposite face of the membrane to the tracks, so as to be electrically isolated from the tracks by the membrane. This conductive layer can also be placed on an insulator covering the tracks. In the embodiments of FIGS. 3A and 4A, this conductive layer is passed through respectively by the slits 302 and/or by the hole 402 over its entire thickness. When the generator and the heat source are in place, this conductive layer is in mechanical and thermal contact with the heat source. In use, this layer makes it possible to distribute the heat in the central parts of the membrane. The thermal contact between the heat source and the tracks is then particularly good, and the efficiency of the generator is particularly high.

Furthermore, although the frame 104 represented above is circular, the frame can have any other shape, for example square, rectangular or hexagonal.

Although the hole 402 of the generator of FIG. 4A is circular, the hole 402 can have any adapted shape, depending on the shape of the heat source, in order to produce a thermal contact with the heat source.

Furthermore, provision can be made for a group of thermoelectric generators according to the embodiments described above. The generators are arranged in an array, for example in a matrix. The generators are connected in series and/or in parallel. Thus, a high electric power is obtained. The various frames of various generators can form a single support comprising an opening under each membrane.

Various embodiments with various variants have been described above. It should be noted that a person skilled in the art may combine various elements of these various embodiments and variants without demonstrating inventive step. In particular, provision can be made for slits such as the slits 302 of the generator of FIG. 3A in the generator of FIG. 4A, the slits extending between the tracks from the hole 402. Provision can be made for the slits 302 of the generator of FIG. 3A and/or the hole 402 of the generator of FIG. 4A in the generator of FIG. 5.

In addition, a thermal contact with the end of a heat source 130 can be produced with the generator 402 having a central hole of FIG. 4A, such as the thermal contact described with respect to FIG. 2, the central hole 402 then having the role of making the central parts of the membrane easily deformable.

1. An electricity generator comprising: a suspended membrane resting on a frame; the membrane having thermoelectric tracks of alternate types connected in series and each having one end on the frame and one end on a central part of the membrane, in which the membrane is deformable; the central parts of the membrane being intended to be in mechanical and thermal contact with a heat source.

2. The generator according to claim 1, in which the membrane is made from a polyimide.

3. The generator according to claim 2, in which the polyimide is thermostable.

4. The generator according to claim 1, in which a treatment of the surface is applied to the membrane.

5. The generator according to claim 1, in which the membrane has a thickness comprised between 10 and 100 μm.

6. The generator according to claim 1, in which the membrane comprises slits which extend between the tracks from a central point of the membrane.

7. The generator according to claim 1, in which the membrane comprises a central hole.

8. The generator according to claim 1, in which the tracks are wider towards the edges than towards the centre of the membrane and, on the suspended parts of the membrane, the spaces between adjacent tracks correspond to radial strips having a width less than 0.5 mm.

9. The generator according to claim 1, in which the central parts of the membrane are coated with a thermally conductive layer intended to form said mechanical and thermal contact.

10. The generator according to claim 1, in which the tracks are made from a doped semiconductor and the types of tracks are the N and P-doping types.

11. A group of generators arranged in an array, comprising generators according claim 1, electrically connected in series and/or in parallel.
